(19) United States
(12) Patent Application Publication
(10) Pub. No.: US 2003/0098695 A1
(43) Pub. Date: May 29, 2003

(54) Circuit and method for measuring capacitance

(76) Inventors: Tsung Hsuan Hsieh, Tainan (TW); Yao Wen Chang, Hsinchu (TW); Tao Cheng Lu, Kaohsiung (TW)

Correspondence Address: BIRCH STEWART KOLASCH & BIRCH, PO BOX 747, FALLS CHURCH, VA, 22040-0747, US

(21) Appl. No.: 09/994,855

(22) Filed: Nov. 28, 2001

(51) Int. Cl. G01R 31/12

(52) U.S. Cl. 324/548

(57) ABSTRACT

A circuit for measuring capacitance of a capacitor that includes a PMOS device, a NMOS device, a first terminal, and a second terminal. The drains of the PMOS and NMOS devices are connected to each other, one end of the first terminal is connected between the drains of the PMOS and NMOS devices, and the other end of the first terminal and one end of the second terminal are connected respectively to two sides of a capacitor. The invention also discloses a method for measuring capacitance of a capacitor by using the circuit mentioned above.

### BACKGROUND OF INVENTION

1. Field of Invention

This invention relates to a circuit and method for measuring capacitance and, in particular, to a circuit and method for measuring the capacitance by one set of PMOS and NMOS devices.

2. Related Art

Accompanying the increase in integration on a semiconductor device, the need to accurately characterize interconnect delay has steadily increased in importance. This is underscored by the fact that modern circuits have become increasingly laden with more metal layers as well as more routing on each layer.

Past on-chip interconnect capacitance techniques have relied on a reference capacitor, a complicated test-structure design or a complicated measurement setup. However, the method described above could only provide pico-farad (pF) resolution capabilities.

To measure tinier capacitance such as femto-farad (fF), scientists have brought out a measurement method, which is called CBCM (Charge-Based Capacitance Measurement). This methodology could be applied to characterize parasitic interconnect capacitances to achieve 0.001 fF.

Referring to FIG. 1, the test structure of the CBCM method consists of a pair of NMOS and PMOS transistors, wherein one NMOS transistor is connected to one PMOS transistor, and the other NMOS and PMOS transistors are connected to each other. A target capacitance C is connected between one set of NMOS and PMOS transistors. The currents flowing through two sets of NMOS and PMOS transistors can be measured, and therefore, the value of target capacitance C can be determined by the difference between the currents. The detail description of the CBCM method is disclosed in “An On-Chip, Interconnect Capacitance Characterization Method with Sub-Femto-Farad Resolution,” Proc. IEEE 1997 Int. Conference on Microelectronic Test Structures, Vol. 10, March 1997. Persons who are skilled in the art should know the CBCM method very well, and an explanation of it is omitted here.

Those skilled in the art should know that the CBCM method assumes two sets of NMOS and PMOS transistors have equal parasitic capacitance. Unfortunately, the actual parasitic capacitances are probably different. Therefore, the capacitance measured by the CBCM method would be inaccurate.

As described before, to provide a circuit and method for measuring small capacitances and minimizing errors in measuring capacitances is an important issue under study.

### SUMMARY OF THE INVENTION

An objective of the invention is to provide a circuit and method for measuring capacitance that can minimize errors while measuring a small capacitance.

To achieve the above objective, the circuit for measuring capacitance of a capacitor C according to the invention includes a PMOS device, an NMOS device, a first terminal, and a second terminal. In this invention, the source and gate of the PMOS device are connected to a first power supply and a second power supply, respectively. The drains of the PMOS and the NMOS devices are connected to each other. The gate and source of the NMOS device are connected to a third power supply and ground, respectively. One end of the first terminal is connected between the drains of the PMOS and NMOS devices, and the other end of it is connected to one side of the capacitor C. One end of the second terminal is connected to the other side of the capacitor C, and the other end of it is connected to a fourth power supply.

In one aspect of the invention, the first power supply provides a stationary voltage Vdd, and the second and third power supplies provide an identical frequency. The currents between the source of the PMOS device and ground is measured while the fourth power supply provides a voltage at the same level with that between the drains of the PMOS and NMOS devices, and while the fourth power supply provides a voltage substantially equal to zero. According to the currents, the capacitance of the capacitor C can be calculated.

This invention also provides a capacitance measurement method that measures the capacitance of the capacitor C with the circuit described above. The method includes the steps of applying a first power supply to the source of the PMOS device, applying a second power supply to the gate of the PMOS device, applying a third power supply to the gate of the NMOS device, providing a fourth power supply to the second terminal and measuring currents between the source of said PMOS device and ground, and determining the capacitance of the capacitor C according to the currents.

In this case, a first current I₁ between the source of the PMOS device and ground is measured while the fourth power supply provides a voltage at the same level with that between the drains of the PMOS and NMOS devices, and a second current I₂ between the source of the PMOS device and ground is measured while the fourth power supply provides a voltage substantially equal to zero.

According to the method of the invention, the NMOS device is turned off while the PMOS device is turned on, and the PMOS device is turned off while the NMOS device is turned on.

As described above, the capacitance of the capacitor C can be determined with equation (1) depending on the first current I₁, the second current I₂, the stationary voltage Vdd, and the frequency F. Equation (1) is shown below:

$$C = \frac{( {I}_{2} - {I}_{1} ) \times F}{Vdd} \qquad ( 1 )$$

According to the invention, the capacitance measurement circuit and method can measure small capacitances by using only one set of PMOS and NMOS devices, so that it is not necessary to consider errors caused by the difference of the parasitic capacitances in the CBCM method.

### BRIEF DESCRIPTION OF THE DRAWINGS

These and other features, aspects and advantages of the invention will become apparent by reference to the following description and accompanying drawings which are given by way of illustration only, and thus are not limitative of the invention, and wherein:

FIG. 1 is a schematic diagram showing a test structure used in the CBCM method;

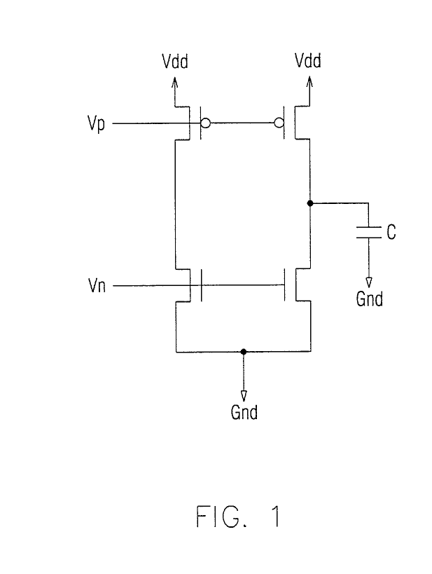

FIG. 2 is a schematic diagram showing a capacitance measurement circuit according to a preferred embodiment of this invention;

FIG. 3 is a coordinate diagram showing the voltages applied to each power supplies of the capacitance measurement circuit according to a preferred embodiment of this invention; and

FIG. 4 is a flow chart showing a capacitance measurement method according to a preferred embodiment of this invention.

### DETAILED DESCRIPTION OF THE INVENTION

The invention will be apparent from the following detailed description, which proceeds with reference to the accompanying drawings, wherein the same references relate to the same elements.

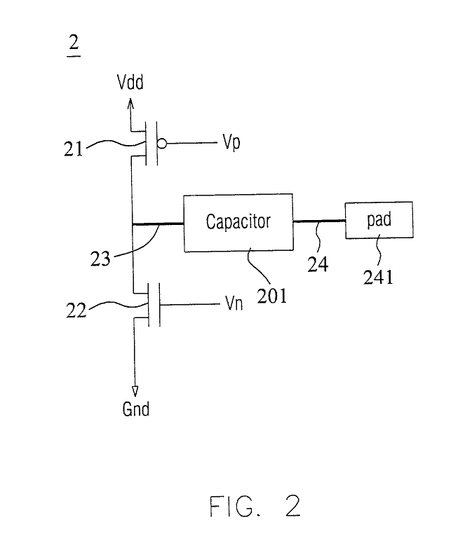

Referring to FIG. 2, a capacitance measurement circuit 2 includes a PMOS device 21, an NMOS device 22, a first terminal 23, and a second terminal 24. The circuit 2 is used to measure the capacitance of a capacitor 201.

The source and gate of the PMOS device 21 are connected respectively to a first power supply Vdd and a second power supply Vp. The drains of the PMOS device 21 and NMOS device 22 are connected to each other. The gate and source of the NMOS device 22 are connected to a third power supply Vn and ground Gnd, respectively. One end of the first terminal 23 is connected between the drains of the PMOS device 21 and NMOS device 22. The other end of the terminal 23 and one end of the second terminal 24 are connected to each sides of the capacitor 201, respectively. The other end of the second terminal 24 is connected to a pad 241, so that a fourth power supply Vt can be applied from the pad 241 to one side of the capacitor 201.

In this case, all of the devices can be formed in a portion of an integrated circuit in a semiconductor chip, wherein the first terminal 23 and the second terminal 24 can be metal lines, the PMOS device 21 can be a PMOS field effect transistor (PMOSFET), and the NMOS device 22 can be an NMOS field effect transistor (NMOSFET). In other word, the PMOS device 21, NMOS device 22, first terminal 23, and second terminal 24 can be formed in a semiconductor chip, and the capacitor 201 can be any two electrically isolated metal devices of the semiconductor chip.

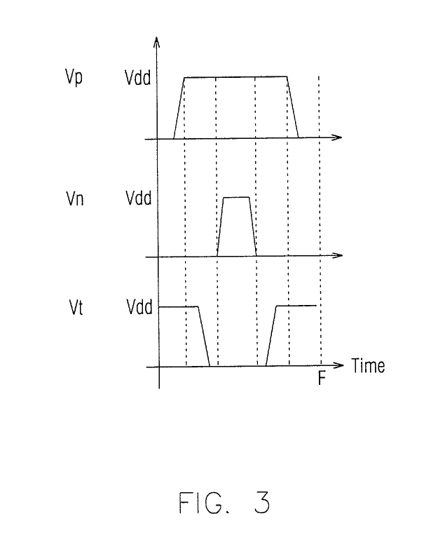

In one embodiment, the first power supply Vdd is a stationary voltage, such as 5V or 12V. The second power supply Vp and the third power supply Vn have an identical frequency F. For example, as shown in FIG. 3, the frequencies of the second power supply Vp and the third power supply Vn are divided into five stages. The second power supply Vp is at a low level in first and fifth stages, and is at a high level in second, third, and fourth stages. The third power supply Vn is at a high level in third stage, and is at a low level in first, second, fourth, and fifth stages. In this case, the high level is equal to the first power supply Vdd, and the low level is equal to zero.

As shown in FIG. 3, the frequency of the fourth power supply Vt is the same with that of second power supply Vp and of third power supply Vn. The fourth power supply Vt is at a high level in first and fifth stages, and is at a low level in third stage. The most important thing is in second and fourth stages, the fourth power supply Vt, respectively, is raised from a low level to a high level and lowered from a high level to a low level, so as to remain at the same level with the voltage of the first terminal 23. Thus, the capacitance of the capacitor 201 is equal to zero.

Alternatively, the fourth power supply Vt is kept at a low level, that is, the fourth power supply Vt is equal to zero, so that the difference between two sides of the capacitor 201 is equal to the voltage of the first terminal 23.

To make the content of the invention clearer, an example is described hereinafter to illustrate the capacitance measurement method.

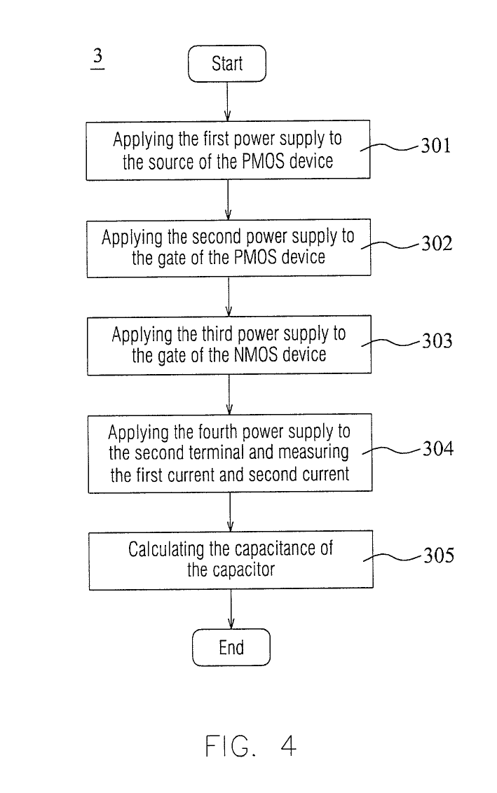

As shown in FIG. 4, the disclosed capacitance measurement method 3 uses the capacitance measurement circuit 2 to measure the capacitance of the capacitor 201. The method 3 includes the steps as shown in FIG. 4. In step 301, the first power supply Vdd is applied to the source of the PMOS device 21, wherein the voltage of the first power supply is a stationary one, such as 5V or 12V.

In step 302, the second power supply Vp is applied to the gate of the PMOS device 21, wherein the second power supply Vp has a frequency F as shown in FIG. 2. In other words, in this step, the second power supply Vp is at a low level in the first stage, is at a high level in second, third and fourth stages, and is at a low level in the fifth stage. The five stages are repeated in turn. The low level mentioned above could be 0V, and the high level is equal to the first power supply Vdd.

In step 303, the third power supply Vn is applied to the gate of the NMOS device 22, wherein the third power supply Vn has a frequency F as shown in FIG. 2. In other words, in this step, the third power supply Vn is at a low level in first and second stages, is at a high level in the third stage, and is at a low level in fourth and fifth stages. The five stages are repeated in turn. The low level mentioned above could be 0V, and the high level is equal to the first power supply Vdd.

As described above, according to the pulses shown in FIG. 3, the NMOS device 22 is turned off while the PMOS device 21 is turned on, and the PMOS device 21 is turned off while the NMOS device 22 is turned on. Thus, in steps 302 and 303, a parasitic capacitance is formed between the source of the PMOS device 21 and ground.

In step 304, the fourth power supply Vt is applied to the second terminal 24. In this embodiment, while the voltage of the fourth power supply Vt is equal to that of the first terminal 23, a first current I₁ is measured between the source of the PMOS device 21 and ground Gnd. To maintain the voltage of the fourth power supply Vt being equal to that of the first terminal 23, the pulse of the fourth power supply Vt is shown in FIG. 3. Alternatively, a second current I₂ is measured between the source of the PMOS device 21 and ground Gnd while the voltage of the fourth power supply Vt is equal to zero.

As described above, the first current I₁ is a current flowing through the parasitic capacitance between the source of the PMOS device 21 and ground Gnd, and the second current I₂ is a current flowing through the parallel capacitance of the capacitance device 201 and the parasitic capacitance between the source of the PMOS device 21 and ground Gnd.

In step 305, the capacitance of the capacitor 201 is calculated according to the first current I₁, second current I₂, first power supply Vdd, and frequency F. In this embodiment, the first current I₁, second current I₂, first power supply Vdd, and frequency F are put into equation (1) to determine the capacitance of the capacitor 201.

Furthermore, in this embodiment, the first current I₁ and second current I₂ can be derived by averaging those measured in a plurality of frequencies F, so as to minimize the deviation and increase the precision of the capacity measured.

While the invention has been described by way of an example and in terms of the preferred embodiment, it is to be understood that the invention is not limited to the disclosed embodiment. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A circuit for measuring capacitance of a capacitor, comprising:
a PMOS device;
an NMOS device, wherein a drain of the NMOS device electrically connects to a drain of the PMOS device;
a first terminal, wherein one end of the first terminal is electrically connected between the drain of the NMOS and the drain of the PMOS, and
the other end of the first terminal connects to the capacitor; and
a second terminal, wherein one end of the second terminal connects to the capacitor.

2. The circuit of claim 1, wherein the first terminal and the second terminal are both metal lines, each of the PMOS device, the NMOS device, the first terminal and the second terminal are formed in a semiconductor chip, and the capacitor is formed by any two metals which are electrical isolated.

3. The circuit of claim 1, wherein a source and a gate of the PMOS device electrically connect to a first power supply and a second power supply respectively, a gate and a source of the NMOS device electrically connect to a third power supply and ground respectively, and the other end of the second terminal electrically connects to a fourth power supply.

4. The circuit of claim 3, wherein the fourth power supply provides a voltage at the same level with a voltage between the drains of the PMOS device and the NMOS device.

5. The circuit of claim 3, wherein the fourth power supply provides a voltage substantially equal to zero.

6. The circuit of claim 3, wherein the first power supply provides a stationary voltage.

7. The circuit of claim 3, wherein the second power supply and the third power supply have an identical frequency.

8. A method for measuring capacitance of a capacitor with a capacitance measurement circuit which comprises a PMOS device, an NMOS device, a first terminal and a second terminal, comprising:
applying a first power supply, which provides a stationary voltage, to a source of the PMOS device;
applying a second power supply to a gate of the PMOS device;
applying a third power supply to a gate of the NMOS device, wherein the second power supply and the third power supply have an identical frequency;
providing a voltage of the fourth power supply equal to a voltage between the drains of the PMOS device and the NMOS device to the second terminal, and measuring a first current between the source of the PMOS device and ground;
providing the voltage of the fourth power supply equal to zero to the second terminal, and measuring a second current between the source of the PMOS device and ground; and
determining the capacitance of the capacitor according to the first current, the second current, the stationary voltage and the frequency.

9. The method of claim 8, wherein the NMOS device is turned off while the PMOS device is turned on.

10. The method of claim 8, wherein the PMOS device is turned off while the NMOS device is turned on.
